(19) United States
(12) Patent Application Publication
(10) Pub. No.: US 2025/0300038 A1
(43) Pub. Date: Sep. 25, 2025

(54) COOLER AND SEMICONDUCTOR DEVICE

(71) Applicant: FUJI ELECTRIC CO., LTD., Kawasaki-shi (JP)

(72) Inventor: Takashi SHIRAKI, Kawasaki-shi (JP)

(73) Assignee: FUJI ELECTRIC CO., LTD., Kawasaki-shi (JP)

(21) Appl. No.: 19/066,935

(22) Filed: Feb. 28, 2025

(30) Foreign Application Priority Data
Mar. 22, 2024 (JP) 2024-045867

(51) Int. Cl. H01L 23/427; H01L 23/538

(52) U.S. Cl. CPC H01L 23/427; H01L 23/538

(57) ABSTRACT

A cooler including: a top plate having a first surface that is flat; a bottom plate having a second surface that is opposite to the first surface of the top plate and is corrugated, the first surface and the second surface facing a flow path of a refrigerant; and a plurality of protruding portions protruding from the second surface of the bottom plate toward the first surface of the top plate. The refrigerant flows into the cooler in a first direction, and flows through the flow path. Any two of the plurality of protruding portions that are immediately upstream or downstream to each other are spaced apart by a first distance in the first direction, and by a second distance in a second direction orthogonal to the first direction. The second surface of the bottom plate has peaks and valleys that alternately appear in the first direction, and that form a waveform extending in the second direction.

### CROSS REFERENCE TO RELATED APPLICATIONS

This application is based upon and claims the benefit of priority to Japanese Patent Application No. 2024-045867, filed on Mar. 22, 2024, the entire contents of which are incorporated herein by reference.

### BACKGROUND OF THE INVENTION

### 1. Technical Field

The present invention relates to a cooler and a semiconductor device.

### 2. Description of the Related Art

A semiconductor device used in a power conversion device such as an inverter device includes a cooler that circulates a refrigerant for dissipating heat generated by a semiconductor element. This type of cooler is provided with a plurality of fins in a flow path for circulating a refrigerant (for example, JP 2006-100293 A, JP 2011-165939 A, and JP 2014-82466 A).

### SUMMARY OF THE INVENTION

In the above-described semiconductor device, it is desired to improve cooling performance of the cooler.

The present invention has been made in view of such a point, and an object thereof is to improve cooling performance of a cooler applied to a semiconductor device.

A cooler according to one aspect of the present invention includes a top plate that forms a flat first surface in a flow path of a refrigerant; a bottom plate that forms a second surface opposite to the first surface in the flow path of the refrigerant; and a plurality of protruding portions erected from the second surface of the bottom plate toward the first surface, in which the plurality of protruding portions are provided such that another protruding portion is disposed at a position translated by a first distance in a first direction substantially parallel to a direction from upstream to downstream in the flow path of the refrigerant and by a second distance in a second direction orthogonal to the first direction, and an apex of a protrusion and an apex of a recess of the second surface of the bottom plate alternately appear in the first direction, each of apexes of the protrusion and each of apexes of the recess are formed in a waveform extending in the second direction.

According to the present invention, it is possible to improve cooling performance of a cooler applied to a semiconductor device.

### BRIEF DESCRIPTION OF THE DRAWINGS

FIG. 1 is a plan view illustrating a configuration example of a cooler according to an embodiment;

FIG. 2 is a plan view illustrating a flow path of a refrigerant in the cooler of FIG. 1;

FIG. 3 is a sectional side view illustrating a configuration example of the cooler taken along line A-A′ in FIG. 1;

FIG. 4 is an equivalent circuit diagram illustrating an example of an electronic circuit including a semiconductor element to be cooled;

FIGS. 5A and 5B are a partially enlarged plan view (FIG. 5A) and a sectional side view (FIG. 5B) illustrating a configuration example of a turbulence generating member of the cooler according to the embodiment;

FIG. 6 is a sectional side view illustrating a flow of a refrigerant in the cooler according to the embodiment;

FIG. 7 is a view illustrating a positional relationship between an apex of a protrusion and an apex of a recess on a corrugated bottom surface of the turbulence generating member;

FIG. 8 is a view illustrating definition of a shape of each part in the turbulence generating member;

FIG. 9 is a plan view illustrating a modification of the arrangement of protruding portion rows in the cooler according to the embodiment;

FIG. 10 is a sectional side view illustrating an example of a shape of the corrugated bottom surface of the turbulence generating member in the cooler of FIG. 9;

FIGS. 11A and 11B are sectional side views illustrating a modification of the configuration of the cooler; and

FIG. 12 is a sectional side view illustrating still another modification of the configuration of the cooler.

### DETAILED DESCRIPTION

Hereinafter, embodiments of the present invention will be described in detail with reference to the drawings. Note that an X axis, a Y axis, and a Z axis in each of the drawings to be referred to are illustrated for the purpose of defining a plane and a direction in the exemplified semiconductor device, cooler, or the like. The X, Y, and Z axes are orthogonal to each other and form a right-handed system. In the following description, a direction parallel to the X axis is referred to as an X direction, a direction parallel to the Y axis is referred to as a Y direction, and a direction parallel to the Z axis is referred to as a Z direction. Also, in a case where each of the X direction, the Y direction, and the Z direction is associated with a direction of an arrow (positive or negative) of a corresponding one of the X axis, the Y axis, and the Z axis illustrated, a “positive side” or a “negative side” is added. The “−X direction” is a minus X direction, and indicates a negative side in the X direction (a direction opposite to a direction of an arrow of the X axis).

In the present specification, the Z direction may be referred to as a vertical direction. In the present specification, “above” and “upper side” are intended to be on the positive side in the Z direction with respect to the reference surface, member, position, and the like, and “below” and “lower side” are intended to be on the negative side in the Z direction with respect to the reference surface, member, position, and the like. For example, when it is described that “the member B is disposed above the member A”, the member B is disposed on the positive side in the Z direction as viewed from the member A. Further, when the “upper surface of the member A” is described, the surface is positioned at the end of the member A on the positive side in the Z direction and faces the positive side in the Z direction. Such directions and surfaces are terms used for convenience of description. Thus, depending on a posture of attachment of the semiconductor device, a correspondence relationship with directions of the X, Y, and Z axes may vary. For example, a surface of the cooler on which a wiring board and a semiconductor element are arranged is referred to as an upper surface of the cooler in the present specification, but is not limited thereto, and may be referred to as a lower surface, a side surface, or the like of the cooler. In addition, an aspect ratio and a size relationship between the members in each drawing are merely schematically represented, and do not necessarily coincide with a relationship in the semiconductor device, the cooler, or the like actually manufactured. For convenience of description, it is also assumed that the size relationship between the respective members is exaggerated. In addition, some reference signs in the drawings are underlined to indicate that a part of the components referred to by the reference signs is a reference sign that refers to the entirety of the components when the part is referred to by another reference sign.

In addition, a semiconductor device to be illustrated in the following description may be applied to, for example, a power conversion device such as an industrial or electrical (for example, an in-vehicle motor's) inverter device. Thus, in the following description, detailed description of the same or similar configuration, function, operation, manufacturing method, and the like as those of the known semiconductor device will be omitted.

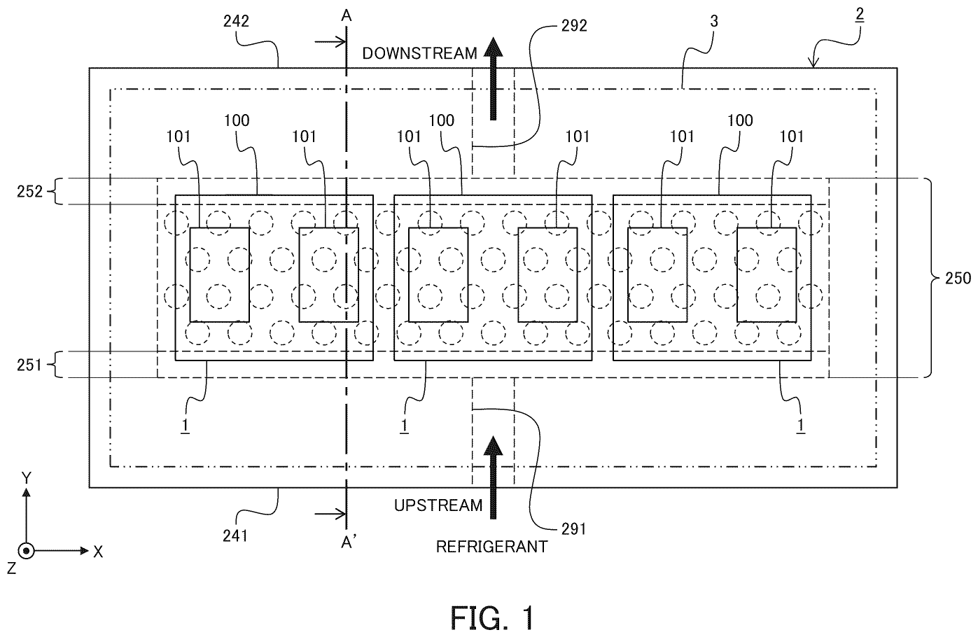

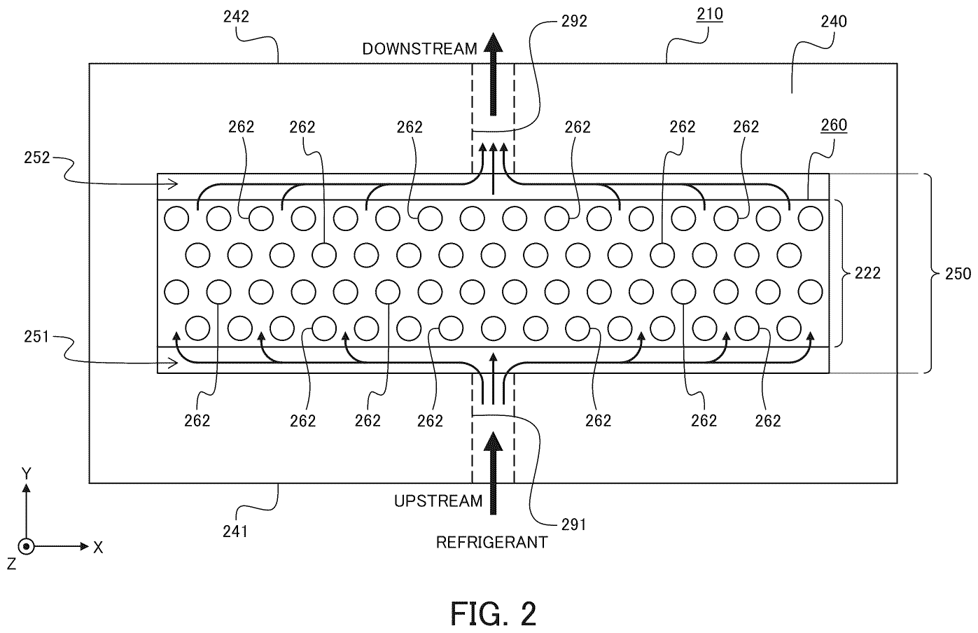

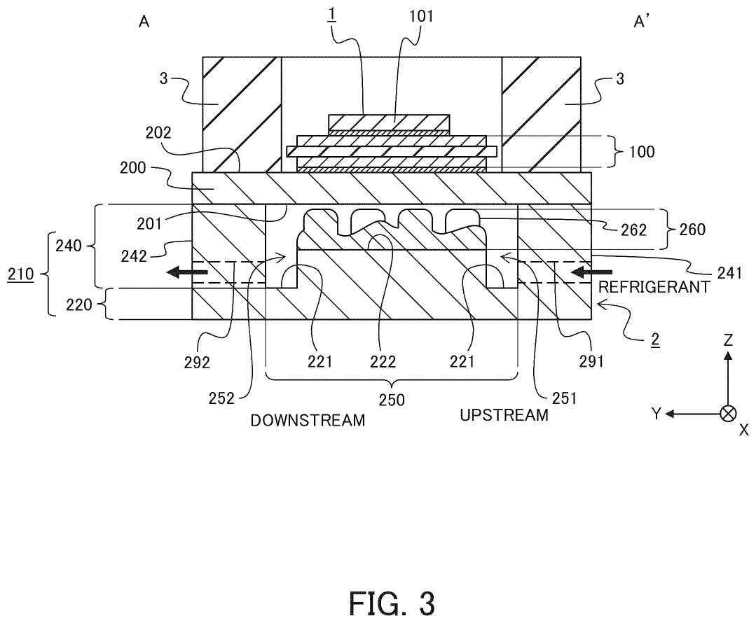

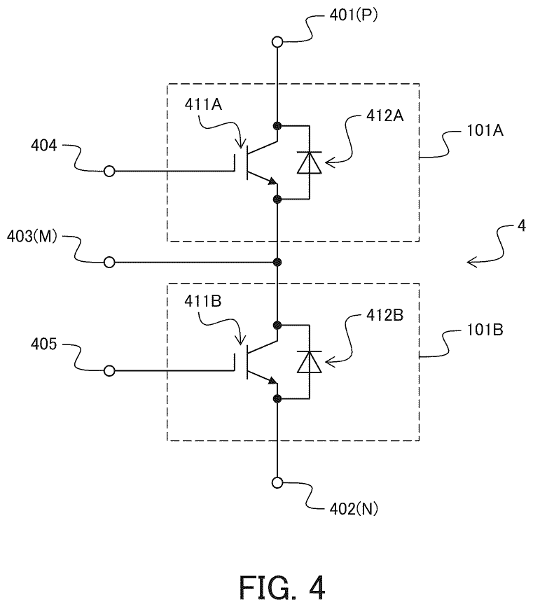

FIG. 1 is a plan view illustrating a configuration example of a cooler according to an embodiment. FIG. 2 is a plan view illustrating a flow path of a refrigerant in the cooler of FIG. 1. FIG. 3 is a sectional side view illustrating a configuration example of the cooler taken along line A-A′ in FIG. 1. FIG. 4 is an equivalent circuit diagram illustrating an example of an electronic circuit including a semiconductor element to be cooled. The side sectional view of FIG. 3 is a view of a portion of the cooler taken along line A-A′ in FIG. 1 on the right side (positive side in the X direction) from the line A-A′ as viewed from the negative side in the X direction.

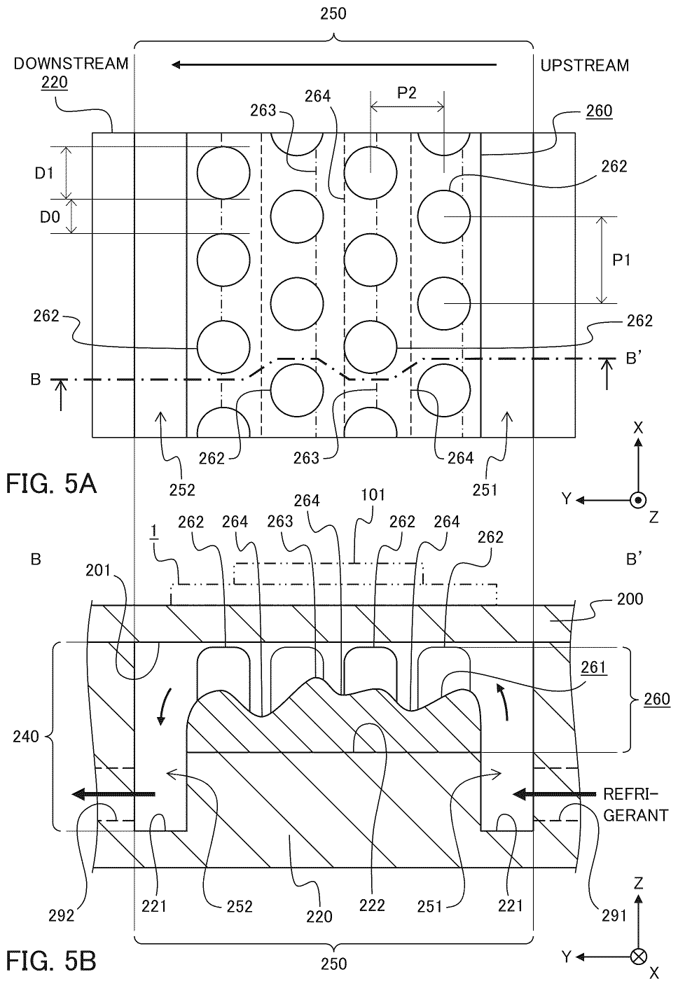

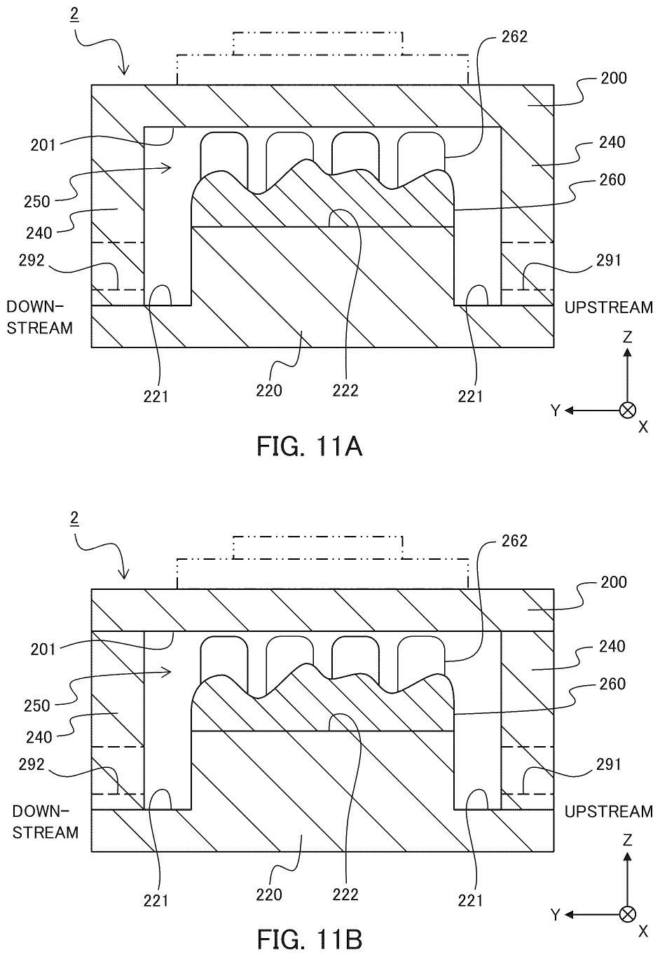

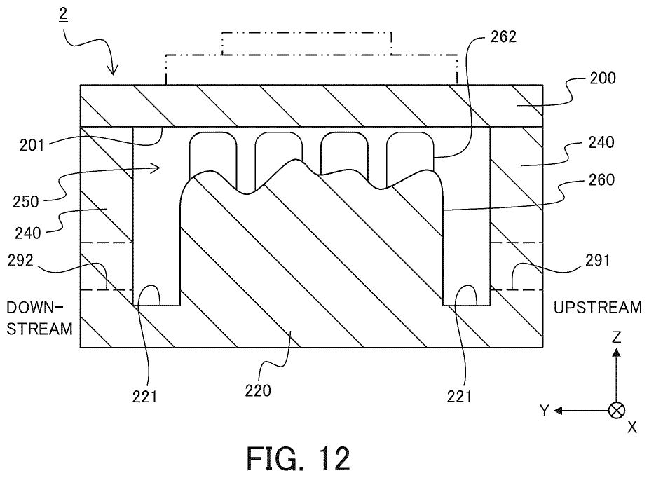

A cooler 2 illustrated in FIGS. 1 to 3 includes a top plate 200 and a water jacket 210 disposed on the side of a lower surface 201 of the top plate 200. The water jacket 210 includes a bottom plate 220 and a peripheral wall portion 240 integrally formed with the bottom plate 220. In the top plate 200, a heating element 1 is disposed on the upper surface 202, and the lower surface 201 is one surface (upper bottom surface) of a flow path 250 of a refrigerant. The bottom plate 220 includes an upper surface (lower bottom surface) 221 facing the lower surface 201 of the top plate 200. The lower bottom surface 221 of the bottom plate 220 has a turbulence generating member disposing region 222 overlapping a region where the heating element 1 is disposed in a plan view of the lower bottom surface 221, and a frame-shaped peripheral wall portion 240 surrounding the turbulence generating member disposing region 222. A turbulence generating member 260 described later with reference to FIGS. 5A and 5B, FIGS. 6 to 8, and the like is disposed on the turbulence generating member disposing region 222. The upper end surface of the peripheral wall portion 240 is bonded to the lower surface 201 of the top plate 200 such that the flow path 250 of the refrigerant in which the turbulence generating member 260 is disposed is defined between the lower surface 201 of the top plate 200 and the turbulence generating member disposing region 222. The top plate 200 is formed using a metal such as aluminum or copper having good thermal conductivity, an epoxy resin containing particles such as carbon or boron nitride (BN) having high thermal conductivity, or the like. The bottom plate 220 and the peripheral wall portion 240 of the water jacket 210 may be separately formed and connected as described later with reference to FIG. 11B. The turbulence generating member 260 may be integrally formed with the turbulence generating member disposing region 222 of the bottom plate 220 as described later with reference to FIG. 12.

The heating element 1 cooled by the cooler 2 may include a wiring board 100 and a semiconductor element (semiconductor chip) 101 mounted on the wiring board 100. In the cooler 2 illustrated in FIGS. 1 to 3, the outer shape of the upper surface 202 of the top plate 200 in a plan view is substantially rectangular (rectangular), and three heating elements 1 are arranged in a region overlapping the flow path 250 of the refrigerant in the upper surface 202 of the top plate 200 along the longitudinal direction (X direction). In the peripheral wall portion 240 of the cooler 2, a first flow hole 291 communicating with the flow path 250 of the refrigerant from one end surface 241 of the pair of end surfaces 241 and 242 positioned at the end in the lateral direction (Y direction) and a second flow hole 292 communicating with the flow path 250 of the refrigerant from the other end surface 242 are formed. In the present embodiment, the first flow hole 291 is referred to as an inlet 291 of the refrigerant, and a second flow hole 292 is referred to as an outlet 292 of the refrigerant. In the exemplified flow path 250 of the refrigerant in the cooler 2, the dimension in a flow path width direction (X direction) is larger than the dimension in a flow direction (Y direction) of the refrigerant. When such a flow path 250 of the refrigerant is formed, a first recess (header portion) 251 for spreading the refrigerant flowing into the flow path 250 of the refrigerant through the inlet 291 in the flow path width direction is formed on the upstream end side of the flow path 250 of the refrigerant. The refrigerant having passed through the first recess 251 flows downstream through between a plurality of protruding portions 262 formed on the turbulence generating member 260. A second recess 252 that guides the refrigerant flowing through the flow path 250 of the refrigerant to the outlet 292 is formed on the downstream end side of the flow path 250 of the refrigerant.

The wiring board 100 and the semiconductor element 101, which are examples of the heating element 1, can be, for example, circuit components forming a half-bridge inverter circuit 4 as illustrated in FIG. 4. The wiring board 100 has a structure in which a conductive plate made of copper or the like is disposed on a front surface and a back surface of an insulating substrate, and may be, for example, a direct copper bonding (DCB) substrate or an active metal brazing (AMB) substrate, but is not limited to a specific configuration. The semiconductor element 101 is disposed on the conductive plate on the front surface with a bonding material such as a solder material interposed therebetween, and the conductive plate on the back surface is bonded to the upper surface 202 of the top plate 200 with a bonding material such as a solder material or a resin interposed therebetween.

A semiconductor element 101A includes a switching element 411A and a diode element 412A connected in anti-parallel to the switching element 411A, and the semiconductor element 101B includes a switching element 411B and a diode element 412B connected in anti-parallel to the switching element 411B. The switching elements 411A and 411B may be an insulated gate bipolar transistor (IGBT) element, a power metal oxide semiconductor field effect transistor (MOSFET) element, a bipolar junction transistor (BJT) element, or the like. The diode elements 412A and 412B may be a free wheeling diode (FWD) element, a Schottky barrier diode (SBD) element, a junction barrier Schottky (JBS) diode element, a merged PN Schottky (MPS) diode element, a PN diode element, or the like. The switching element 411A and the switching element 411B are connected in series, a collector of the switching element 411A is connected to a first main terminal 401 provided in a case 3, and an emitter of the switching element 411B is connected to a second main terminal 402 provided in the case 3.

As illustrated in FIG. 3, the case 3 may be a frame-shaped insulating member disposed on the upper surface 202 of the top plate 200. In the case 3, a first main terminal 401 and a second main terminal 402 (not illustrated in FIG. 3), a third main terminal 403 connected to the emitter of the switching element 411A and the collector of the switching element 411B, a first control terminal 404 connected to the gate of the switching element 411A, and a second control terminal 405 connected to the gate of the switching element 411B are arranged. Note that the electronic circuit of the circuit component to be cooled is not limited to the half-bridge inverter circuit 4 illustrated in FIG. 4. In addition, the configuration of the wiring board 100 in the heating element 1, the type, number, layout, and the like of the semiconductor elements 101 can be appropriately changed. The semiconductor device to which the cooler 2 of the present embodiment can be applied may be a semiconductor device in which the case 3 is omitted, for example, a dual inline package (DIP) type resin-sealed semiconductor device sometimes referred to as a semiconductor package.

Next, a configuration example of the cooler 2 according to the embodiment will be described in detail. FIGS. 5A and 5B are a partially enlarged plan view (FIG. 5A) and a sectional side view (FIG. 5B) illustrating a configuration example of a turbulence generating member of the cooler according to the embodiment. The sectional side view of FIG. 5B is a view of a portion of the cooler 2 taken along line B-B′ of FIG. 5A, the portion being above the line B-B′ (on the positive side in the X direction), as viewed from the negative side in the X direction.

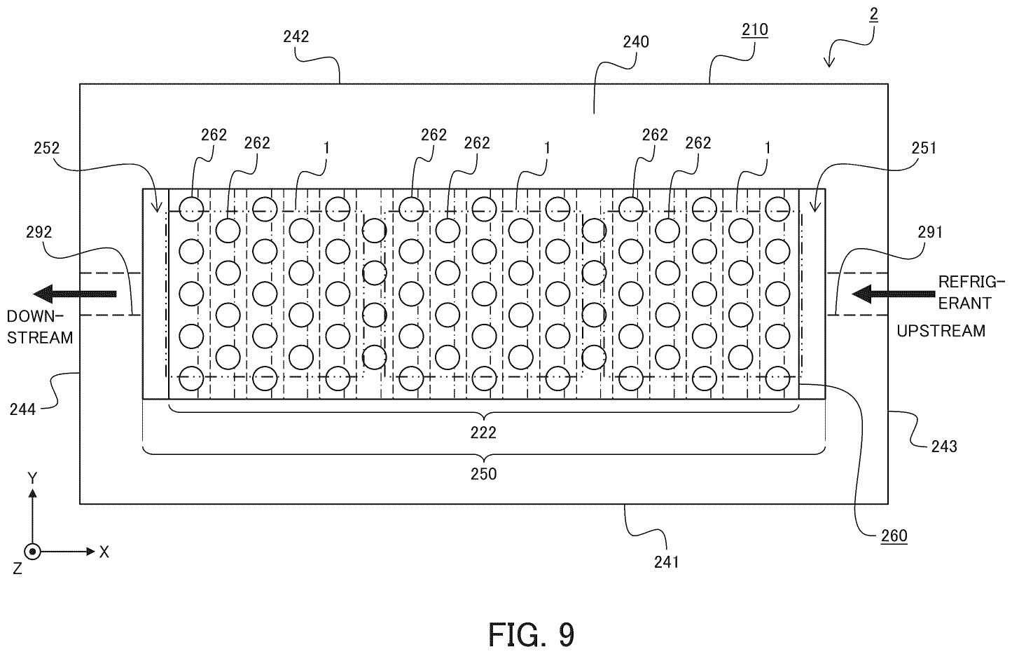

In the cooler 2 of the present embodiment, as described above, the turbulence generating member 260 having the plurality of protruding portions 262 is disposed on the turbulence generating member disposing region 222 provided on the bottom plate 220 of the water jacket 210. The turbulence generating member 260 includes a corrugated bottom surface 261 facing the lower surface 201 of the top plate 200 and the plurality of protruding portions 262 protruding upward (toward the lower surface 201 of the top plate 200) from the corrugated bottom surface 261. In the cooler 2 illustrated in FIGS. 5A and 5B, the refrigerant flows from the negative side in the Y direction toward the positive side in the Y direction. In the following description, with respect to the flow path 250 of the refrigerant, a position close to the inlet 291 of the refrigerant in the Y direction is defined as upstream, and a position close to the refrigerant outlet 292 is defined as downstream. “Upstream” and “downstream” in the present specification may indicate a relative positional relationship of the refrigerant in the flow path 250. The inlet 291 and the outlet 292 may be provided on the end surfaces 243 and 244 on the short sides of the peripheral wall portion 240 as illustrated in FIG. 9. The recesses 251 and 252 on the upstream side and the downstream side of the flow path 250 of the refrigerant may be omitted, and the inlet 291 and the outlet 292 may be provided on the side of the turbulence generating member disposing region 222. However, it is preferable to provide the recesses 251 and 252 because turbulence is easily generated and heat is easily equalized.

In the turbulence generating member 260, for example, as illustrated in FIG. 5A, a row of protruding portions which is a set of the plurality of protruding portions 262 arranged at an interval P1 in the X direction is arranged at an interval P2 in the Y direction. The interval P1 is a distance between the center of the protruding portion 262 and the center in a plan view. The two rows of protruding portions adjacent to each other at the interval P2 in the Y direction are arranged such that the positions of the protruding portions 262 in the X direction are shifted from each other by a distance P1/2, which may be referred to as a staggered arrangement. Therefore, the positions of the protruding portions 262 in the X direction coincide with each other in the two protruding portion rows separated by twice the interval P2 in the Y direction (that is, the interval (2×P2)). That is, assuming that a certain row of protruding portions is a first row of protruding portions, an adjacent row of protruding portions is a second row of protruding portions, and a row of protruding portions adjacent to the second row of protruding portions is a third row of protruding portions, the positions of the protruding portions 262 in the X direction in the first row of protruding portions and the third row of protruding portions coincide with each other. Each of the protruding portions 262 is not a continuous mountain ridge shaped protrusion but is discretely arranged and has a substantially columnar shape. The relationship between a diameter D1 of the protruding portion 262 and a gap DO between the two protruding portions 262 adjacent in the X direction in a plan view is not limited to a specific relationship. The outer shape of each protruding portion 262 is not limited to a substantially cylindrical shape, and may be a polygonal columnar shape or any other convex shape such as a hemispherical shape.

The protruding portions 262 in the turbulence generating member 260 according to the present embodiment are formed on the corrugated bottom surface 261 facing lower surface 201 of top plate 200. As illustrated in FIGS. 5A and 5B, the corrugated bottom surface 261 is formed such that when viewed in a first direction (Y direction) that is a flowing direction (direction from upstream to downstream) of the refrigerant, an apex 263 of a protrusion and an apex 264 of a recess are repeated, and each of the apexes 263 and 264 extends in a second direction (X direction) orthogonal to the first direction. That is, the corrugated bottom surface 261 is provided with line-shaped protrusions or recesses in the second direction perpendicular to the flowing direction (first direction) in a stripe manner (line-shaped structure). Such a turbulence generating member 260 is disposed on the turbulence generating member disposing region 222 of the bottom plate 220 so as to overlap at least the heating element 1 disposed on the upper surface 202 of the top plate 200 in a plan view. Specifically, it is preferable that at least 50% or more, and more preferably 80% or more of areas overlap in a plan view from the viewpoint of cooling efficiency.

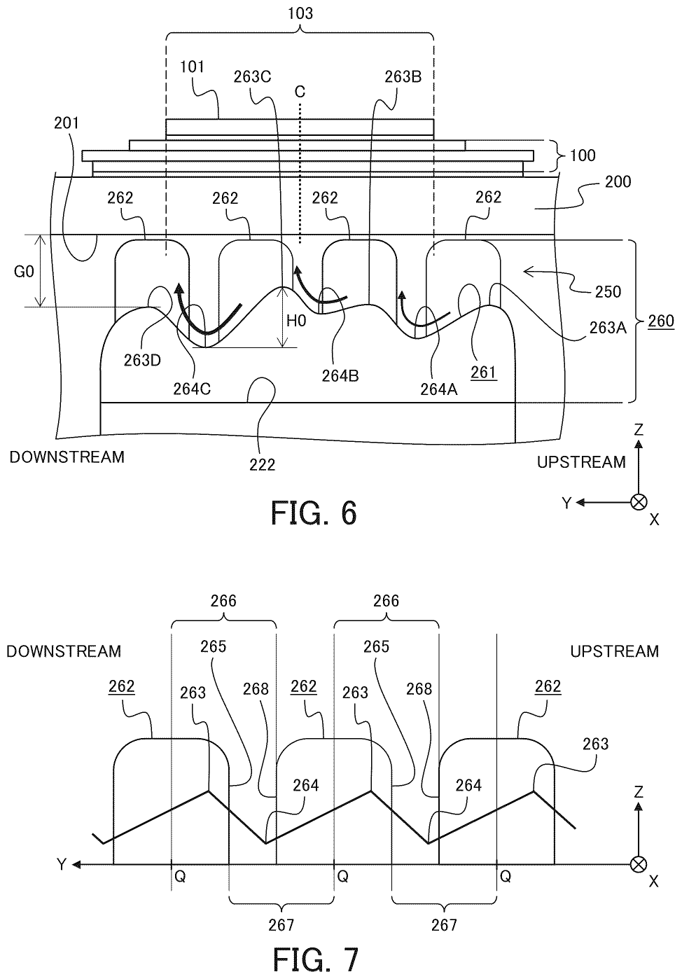

FIG. 6 is a sectional side view illustrating a flow of a refrigerant in the cooler according to the embodiment. FIG. 6 illustrates the top plate 200 and the turbulence generating member 260 illustrated in FIG. 5B in an enlarged manner. Hatching indicating the cross sections of the top plate 200, the bottom plate 220, and the turbulence generating member 260 is omitted. In the following description, only when an apex of a specific protrusion (i.e., a peak) on the corrugated bottom surface 261 of the turbulence generating member 260 is referred to, a corresponding alphabet is added after the reference sign “263”, and only when an apex of a specific recess (i.e., a valley) is referred to, a corresponding alphabet is added after the reference sign “264”.

In the turbulence generating member 260 in the cooler 2 of the present embodiment, as illustrated in FIG. 5A and the like, the protruding portions 262 of the protruding portion rows adjacent to each other at the interval P2 in the Y direction are shifted by the distance P1/2 in the X direction, and the protrusion and the recess of the corrugated bottom surface 261 are formed corresponding to each protruding portion 262 (protruding portion row). Therefore, the flow of the refrigerant in a plan view of the corrugated bottom surface 261 is a flow that repeats branching and merging from upstream to downstream. A part of the refrigerant that repeats branching and merging (that is, meanders) generates a flow of the refrigerant that wound up when colliding with the protruding portion 262 and branching, and induces stirring between the refrigerant flowing at a position close to the lower surface 201 of the top plate 200 and the refrigerant flowing at a position close to the corrugated bottom surface 261 of the turbulence generating member 260.

Furthermore, the turbulence generating member 260 according to the present embodiment has the corrugated bottom surface 261 as described above. Therefore, a part of the refrigerant flowing from the upstream to the downstream moves in a direction away from the lower surface 201 of the top plate 200 along a downward inclined surface from the apex 263 of the protrusion toward the apex 264 of the recess, and then moves in a direction toward the lower surface 201 of the top plate 200 along an upward inclined surface from the apex 264 of the recess toward the apex 263 of the protrusion. That is, in the cooler 2 of the present embodiment, as indicated by an arrow in FIG. 6, a flow of the refrigerant wound up is also generated by the corrugated bottom surface 261. As described above, the flow of the refrigerant in a plan view of the corrugated bottom surface 261 repeats branching and merging from the upstream to the downstream. Therefore, in the flow path 250 of the refrigerant in which the turbulence generating member 260 according to the present embodiment is disposed, turbulence generated by meandering (branching and merging) of the refrigerant as seen in a plan view of the corrugated bottom surface 261 is increased by the flow of the refrigerant wound up by the inclined surface of the corrugated bottom surface 261. That is, the stirring between the refrigerant, at a temperature of which has increased due to heat exchange between the top plate 200 and the refrigerant transferred from the heating element 1, at a position close to the lower surface 201 of the top plate 200 and the refrigerant, at a low temperature, at a position close to the corrugated bottom surface 261 is promoted. Therefore, as compared with the case where the bottom surface of the turbulence generating member 260 is flat, the heat exchange is effectively performed between the top plate 200 and the refrigerant transferred from the heating element 1 also on the downstream side in the flow path 250 of the refrigerant, and the thermal resistance decreases.

In the cooler disclosed in JP 2006-100293 A, JP 2011-165939 A, and JP 2014-82466 A, a plurality of fins that can correspond to the plurality of protruding portions 262 in the turbulence generating member 260 according to the present embodiment are formed in the flow path of the refrigerant. However, JP 2006-100293 A, JP 2011-165939 A, and JP 2014-82466 A do not disclose or suggest a configuration corresponding to the corrugated bottom surface 261 in the turbulence generating member 260, and the upper bottom surface and the lower bottom surface in the flow path of the refrigerant are flat surfaces. Therefore, the cooler 2 including the turbulence generating member 260 according to the present embodiment can improve the cooling performance as compared with the cooler disclosed in JP 2006-100293 A, JP 2011-165939 A, and JP 2014-82466 A and the like in the related art.

In particular, as illustrated in FIG. 6, by shortening the distance from an apex 263C of the protrusion close to a center C of an active portion (region overlapping the semiconductor element 101 in the heating element 1 in a plan view) 103 having the highest temperature to the lower surface 201 of the top plate 200, it is possible to further increase the flow velocity and the degree of turbulence of the refrigerant on the upstream side of the center C of the active portion 103. Therefore, the refrigerant having a higher temperature due to the heat exchange at the center C of the active portion 103 and the refrigerant having a low temperature at the position close to the corrugated bottom surface 261 are effectively stirred, and the heat exchange between the top plate 200 and the refrigerant on the upstream side of the center C of the active portion 103 is effectively performed. Further, as illustrated in FIG. 6, by making a distance GO from an apex 263D of the protrusion positioned most downstream to the lower surface 201 of the top plate 200 longer than the distance from the apex 263C of the protrusion positioned upstream to the lower surface 201, the flow velocity of the refrigerant at the downstream end of the turbulence generating member 260 can be reduced, and the pressure loss of the refrigerant flowing in the section (refer to FIG. 5B) from the downstream end of the turbulence generating member 260 to the outlet 292 can be reduced.

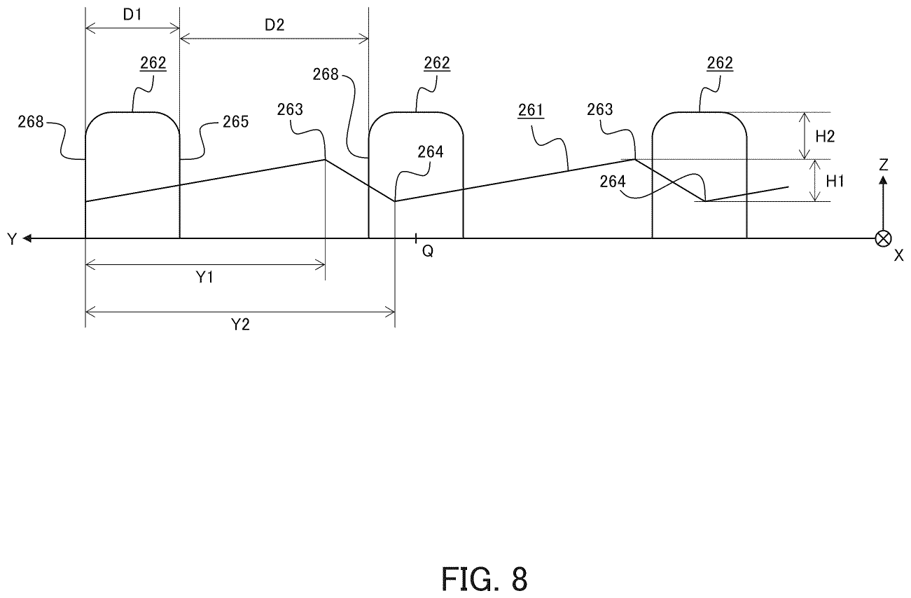

The corrugated bottom surface 261 of the turbulence generating member 260 is not limited to the shapes illustrated in FIGS. 5B and 6. The shape of the corrugated bottom surface 261 of the turbulence generating member 260 according to the present embodiment will be described in more detail with reference to FIGS. 7 and 8.

FIG. 7 is a view illustrating a positional relationship between an apex of a protrusion (a peak) and an apex of a recess (a valley) on a corrugated bottom surface of the turbulence generating member. FIG. 8 is a view illustrating definition of a shape of each part in the turbulence generating member.

In the corrugated bottom surface 261 of the turbulence generating member 260 according to the present embodiment, as illustrated in FIG. 7, the position of the apex 263 of the protrusion in the first direction (Y direction) from the upstream to the downstream is preferably between (within the first section 266) a center Q of the protruding portion 262 and an end 268 on the downstream side of the adjacent protruding portion 262 on the upstream side to the protruding portion 262 in a plan view of a plane (YZ plane) including the first direction. On the other hand, the position of the apex 264 of the recess in the first direction is preferably between (within the second section 267) the upstream end 265 of the protruding portion 262 and the center Q of the protruding portion 262 adjacent to the protruding portion 262 on the upstream side after the above condition is satisfied.

Note that the position of the apex 263 of the protrusion and the position of the apex 264 of the recess are preferably set such that the distance from the position of the apex 264 of the recess to the position of the apex 263 of the protrusion adjacent on the downstream side in the first direction is shorter than the distance to the position of the apex 263 of the protrusion adjacent on the upstream side. In this way, an inclination angle with respect to the upper surface of the turbulence generating member disposing region 222 in the section from the apex 264 of the recess to the apex 263 of the protrusion positioned on the downstream side of the recess can be increased, and the flow in the direction toward the lower surface 201 of the top plate 200 of the refrigerant flowing along the corrugated bottom surface 261 in the first direction and passing through the recess (the flow for winding up the refrigerant) can be promoted. The relationship between the number of protrusions of the corrugated bottom surface 261 and the number of protruding portions 262 in the first direction (Y direction) is not limited to the relationship of 1:1, and may be, for example, 1:N (N is an integer of 2 or more).

Next, the relationship between the shape of the corrugated bottom surface 261 of the turbulence generating member 260 and the thermal resistance of the cooler 2 according to the present embodiment will be described with reference to FIG. 8. FIG. 8 illustrates a case where a height H1 of the wave of the corrugated bottom surface 261 in the turbulence generating member 260 (the distance from the apex 264 of the adjacent recess to the apex 263 of the protrusion in the vertical direction (Z direction)) and a height H2 of the protruding portion 262 (the distance from the apex 263 of the protrusion to the upper end of the protruding portion 262) are constant. In addition, in the turbulence generating member 260 of FIG. 8, the position of a distance Y1 and the position of a distance Y2 on the negative side in the Y direction from the end 268 on the downstream side of the protruding portion 262 on the most downstream (left end) are set as the position of the apex 263 of the protrusion and the position of the apex 264 of the recess of the corrugated bottom surface 261. As a result of examining the relationship between a height ratio H1/H2 and a thermal resistance when a dimension D1 of the protruding portion 262 and a gap D2 between the protruding portions 262 in the first direction (Y direction) were set to D1=4.4 mm and D2=8.8 mm, respectively, the inventor of the present application has found the following.

In a case where the height H2 is set to 2 mm, when the height ratio H1/H2 is in a range of 1.4≥H1/H2≥0.2, the thermal resistance is smaller than that in a case where the bottom surface of the turbulence generating member 260 is flat (that is, the efficiency of heat exchange is improved). In particular, when the height ratio H1/H2 is within the range of 1≥H1/H2≥0.6, the reduction rate of the thermal resistance is larger than that when the bottom surface of the turbulence generating member 260 is flat (for example, the amount is reduced by 3% to 6%).

In addition, as a result of examining the relationship between the distance Y1 and the thermal resistance when the dimension D1 of the protruding portion 262 and the gap D2 between the protruding portions 262 in the first direction, the height ratio H1/H2, and the distance Y2 are constant, the inventor of the present application has found the following.

When a ratio Y1/(D1+D2) of the distance Y1 from the end 268 on the downstream side of the protruding portion 262 to the apex 263 of the protrusion positioned on the upstream side to the interval D1+D2 of the protruding portion 262 (the distance between the end 265 on the upstream side of the adjacent protruding portions 262 in the first direction) is 1.0≥Y1/(D1+D2)≥0.5, the thermal resistance becomes small (that is, the efficiency of heat exchange is improved) as compared with the case where the bottom surface of the turbulence generating member 260 is flat. In particular, when the ratio Y1/(D1+D2) is set within the range of 0.84≥ Y1/(D1+D2)≥0.67, the reduction rate of the thermal resistance becomes large as compared with the case where the bottom surface of the turbulence generating member 260 is flat (for example, the amount is reduced by 3% to 6%).

Further, as a result of examining the relationship between the distance Y2 and the thermal resistance when the interval D1+D2 between the protruding portions 262, the height ratio H1/H2, and the distance Y1 are constant, the inventor of the present application has found the following.

When the ratio Y2/(D1+D2) of the distance Y2 from the end 268 on the downstream side of the protruding portion 262 to the apex 264 of the recess positioned on the upstream side to the interval D1+D2 of the protruding portion 262 is in the range of 1.26≥Y2/(D1+D2)≥0.74, the thermal resistance becomes small (that is, the efficiency of heat exchange is improved) as compared with the case where the bottom surface of the turbulence generating member 260 is flat. In particular, when the distance ratio Y2/(D1+D2) is within the range of 1.09≥Y2/(D1+D2)≥0.91, the reduction rate of the thermal resistance is larger than that when the bottom surface of the turbulence generating member 260 is flat (for example, the amount is reduced by 3% to 6%).

Note that the relationship between the shape of the turbulence generating member 260 and the thermal resistance described above with reference to FIGS. 7 and 8 is an example of a relationship in a specific shape in which the protruding portions 262 are arranged to overlap the periodic row structure of the corrugated bottom surface 261. In the turbulence generating member 260 according to the present embodiment, as described above with reference to FIGS. 5A, 5B, and 6, the height of the apex 263 of the protrusion arranged in the first direction on the corrugated bottom surface 261 (the distance from the lower surface 201 of the top plate 200) and the height of the apex 264 of the recess may not be constant. In addition, the distance between the apex 263 of the protrusion and the distance between the apex 264 of the recess may not be constant. Further, the interval P2 (refer to FIG. 5A) between the protruding portion rows adjacent to each other in the first direction (Y direction) from the upstream toward the downstream may have a relationship of P2≤D1 with respect to the dimension D1 of the protruding portion 262 in the first direction.

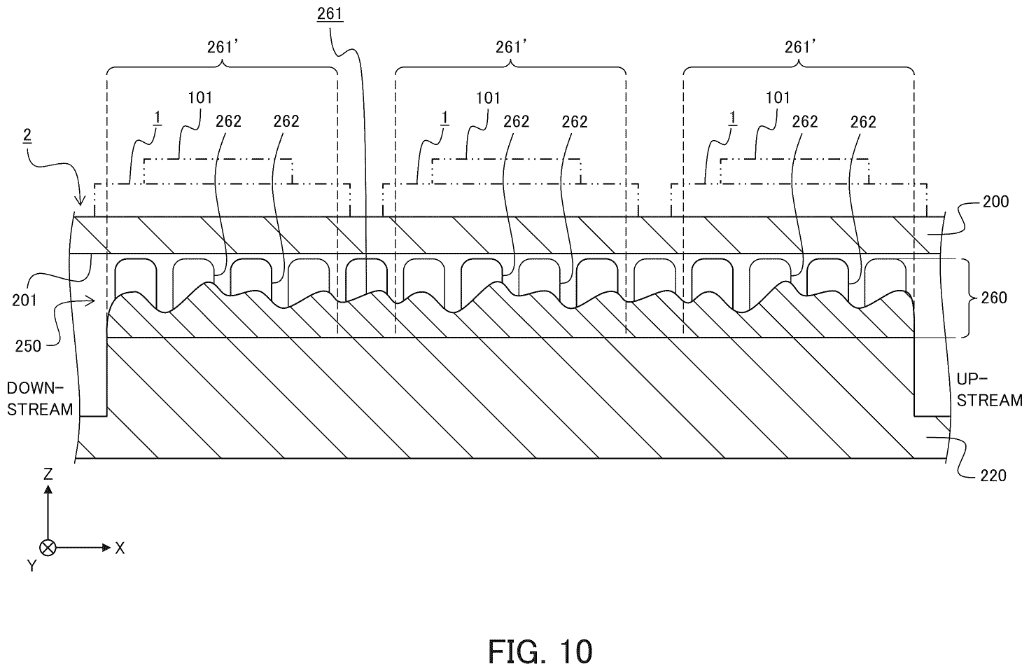

FIG. 9 is a plan view illustrating a modification of the arrangement of protruding portion rows in the cooler according to the embodiment. FIG. 10 is a sectional side view illustrating an example of a shape of the corrugated bottom surface of the turbulence generating member in the cooler of FIG. 9. In the cooler 2 illustrated in FIG. 9, the top plate 200 is not illustrated. FIG. 10 is a view of the cooler 2 in FIG. 9 as viewed from the negative side in the Y direction in a portion above a cutting line (positive side in the Y direction) when the turbulence generating member 260 is cut along the cutting line extending in the X direction so as not to pass through the protruding portion 262 of the turbulence generating member 260.

In the flow path 250 of the refrigerant defined in the cooler 2, as illustrated in FIGS. 9 and 10, the inlet 291 of the refrigerant may be formed on a third end surface 243 positioned on the positive side in the X direction among the third end surface 243 and a fourth end surface 244 of the peripheral wall portion 240 positioned at the end in the longitudinal direction (X direction), and the refrigerant outlet 292 may be formed in the fourth end surface 244 positioned on the negative side in the X direction. In the cooler 2 illustrated in FIGS. 9 and 10, the first direction from the upstream toward the downstream is the −X direction, and the arrangement direction of the plurality of protruding portions 262 included in one protruding portion row and the arrangement direction of the protruding portion row are changed from the directions illustrated in FIGS. 2 and 5A to directions rotated by 90 degrees in the XY plane. In the corrugated bottom surface 261 of the turbulence generating member 260 of the cooler 2 illustrated in FIGS. 9 and 10, the extending direction of the apex 263 of the protrusion and the apex 264 of the recess repeated in the flowing direction of the refrigerant is changed to the Y direction.

In the cooler 2 illustrated in FIGS. 9 and 10, the refrigerant flows while repeatedly branching and merging along a direction substantially parallel to the long side in the XY plane view, and sequentially passes through three regions overlapping the three heating elements 1 disposed on the upper surface of the top plate 200. For example, as illustrated in FIG. 10, the corrugated bottom surface 261 in the cooler 2 may be formed with a unit waveform 261′ that overlaps one heating element 1 described above with reference to FIGS. 5A and 5B and FIGS. 6 to 8 in each region overlapping three heating elements 1 in the flowing direction (−X direction) of the refrigerant. With such a corrugated bottom surface 261, whenever the refrigerant flowing in the −X direction as a whole passes through the center of the semiconductor element 101 (active portion) disposed on one heating element 1, the refrigerant whose temperature has increased due to the heat exchange flowing through the position close to the top plate 200 and the refrigerant whose temperature is low and flowing through the position close to the corrugated bottom surface 261 are effectively stirred, and a decrease in the heat exchange efficiency in the active portion on the downstream can be suppressed. The shape of the corrugated bottom surface 261 of the turbulence generating member 260 and the arrangement of the protruding portions 262 in the cooler 2 are not limited to the shape and arrangement illustrated in FIG. 10, and can be changed as appropriate.

FIGS. 11A and 11B are sectional side views illustrating a modification of the configuration of the cooler. FIG. 12 is a sectional side view illustrating still another modification of the configuration of the cooler. The sectional side views of FIGS. 11A and 11B and FIG. 12 correspond to the sectional side view of FIG. 5B.

As described above, the peripheral wall portion 240 of the cooler 2 according to the present embodiment may not be integrally formed with the bottom plate 220. As illustrated in FIG. 11A, the peripheral wall portion 240 may be integrally formed with the top plate 200 so as to protrude downward from the outer peripheral portion of the lower surface 201 of the top plate 200. In this case, for example, the lower surface of the peripheral wall portion 240 and the outer peripheral portion of the upper surface (lower bottom surface) 221 of the bottom plate 220 are bonded by a bonding material (not illustrated). The top plate 200 having the peripheral wall portion 240 and the bottom plate 220 may be fastened by bolts with a packing interposed between the lower surface of the peripheral wall portion 240 and the upper surface (lower bottom surface) 221 of the bottom plate 220, for example. In addition, as illustrated in FIG. 11B, the peripheral wall portion 240 may be separate from the top plate 200 and the bottom plate 220, and the upper surface and the lower surface of the peripheral wall portion 240 may be bonded to the lower surface 201 of the top plate 200 and the upper surface 221 of the bottom plate 220, respectively, by a bonding material. The top plate 200, the peripheral wall portion 240, and the bottom plate 220 may be fastened by bolts with a packing interposed therebetween, for example.

Although not described in detail with reference to the drawings, the upper surface of the protruding portion 262 may be in contact with the lower surface 201 of the top plate 200 or may be bonded to the lower surface 201 with a bonding material.

Furthermore, in the cooler 2 according to the present embodiment, as illustrated in FIG. 12, the turbulence generating member 260 may be integrally formed with the turbulence generating member disposing region 222 as a part of the bottom plate 220. The turbulence generating member 260 integral with or separate from the bottom plate 220 can be manufactured by, for example, press working or injection molding using a mold, three-dimensional molding by a 3D printer, or the like. For forming the turbulence generating member 260 separate from the bottom plate 220, a metal material same as or different from the bottom plate 220, a resin material having high thermal conductivity, or the like can be used. As an example, the bottom plate 220 and the turbulence generating member 260 are formed using a metal such as aluminum or copper having good thermal conductivity, an epoxy resin containing particles such as carbon or boron nitride (BN) having excellent thermal conductivity, or the like. The turbulence generating member 260 separate from the bottom plate 220 can be attached to the turbulence generating member disposing region 222 of the bottom plate 220 by a known method, for example, by bonding with a bonding material, screwing, or fitting such as snap-fitting.

The inlet 291 of the refrigerant and the outlet 292 of the refrigerant in the cooler 2 according to the present embodiment are not limited to the peripheral wall portion 240, and may be formed in the bottom plate 220 or the top plate 200.

The embodiment of the cooler 2 and the semiconductor device according to the present invention is not limited to the above embodiment, and various changes, substitutions, and modifications may be made without departing from the spirit of the technical idea. Further, when the technical idea may be implemented in another method by the progress of the technology or another derived technology, the technical idea may be carried out by using the method thereof. Therefore, the claims cover all implementations that may be included within the scope of the technical idea.

The semiconductor device to which the cooler 2 according to the present embodiment is applied is not limited to one having three sets of the above-described wiring board 100 and semiconductor element 101. In the semiconductor device, a set of the wiring board 100 and the semiconductor element 101 may be one, or a circuit different from the inverter circuit may be formed.

The semiconductor device of the above-described embodiment can be applied to, for example, an industrial power conversion device such as an inverter device that drives a motor of an elevator, an escalator, an air conditioning system of a building, or the like. Note that the application of the semiconductor device is not limited to specific applications. For example, the semiconductor device can also be applied to a power conversion device such as an inverter device that drives a motor of a vehicle such as a four-wheeled automobile, a two-wheeled vehicle, or a railway vehicle. In addition, the semiconductor device of the above-described embodiment is not limited to the inverter device, and may provide other functions. Furthermore, the heating element 1 to be cooled by the cooler 2 described above is not limited to the one having the wiring board 100 and the semiconductor element 101 (that is, the component constituting the semiconductor device).

Hereinafter, feature points in the above-described embodiments will be summarized.

A cooler according to the above-described embodiment includes a top plate that forms a flat first surface in a flow path of a refrigerant; a bottom plate that forms a second surface opposite to the first surface in the flow path of the refrigerant; and a plurality of protruding portions erected from the second surface of the bottom plate toward the first surface, in which the plurality of protruding portions are provided such that another protruding portion is disposed at a position translated by a first distance in a first direction substantially parallel to a direction from upstream to downstream in the flow path of the refrigerant and by a second distance in a second direction orthogonal to the first direction, and an apex of a protrusion and an apex of a recess of the second surface of the bottom plate alternately appear in the first direction, each of apexes of the protrusion and each of apexes of the recess are formed in a waveform extending in the second direction.

In the cooler according to the above-described embodiment, the apex of the protrusion is positioned between a center of a first protruding portion in the first direction and a downstream end of a second protruding portion on the immediately upstream side of the first protruding portion, and the apex of the recess is positioned between an upstream end of the first protruding portion and a center of the second protruding portion in the first direction.

In the cooler according to the above embodiment, a distance from the apex of the recess to the apex of the protrusion on the downstream side in the first direction is shorter than a distance from the apex of the recess to the apex of the protrusion on the upstream side.

In the cooler according to the above embodiment, a wiring board and a semiconductor element can be mounted on a back surface of the first surface of the top plate, and a distance from an apex of a protrusion close to a center of a region where the semiconductor element is mounted in a plan view of the first surface of the top plate among apexes of the protrusions of the corrugated bottom surface to the first surface of the top plate is shorter than a distance from an apex of another protrusion to the first surface.

In the cooler according to the above embodiment, a distance from an apex of a protrusion positioned most downstream in the first direction among apexes of the protrusions of the corrugated bottom surface to the first surface of the top plate is longer than a distance from an apex of another protrusion to the first surface.

In the cooler according to the above embodiment, a ratio H1/H2 of a distance H1 from the apex of the protrusion to the apex of the recess on the corrugated bottom surface to a distance (height) H2 from the apex of the protrusion to the upper end of the protruding portion is within the range of 1.4≥H1/H2≥0.2.

In the cooler according to the above embodiment, a ratio Y1/(D1+D2) of a distance Y1 from a downstream end of the first protruding portion to the apex of the protrusion in the first direction to a distance D1+D2 from a downstream end of the first protruding portion to a downstream end of the second protruding portion is within a range of 1.0≥Y1/(D1+D2)≥0.5.

In the cooler according to the above embodiment, a ratio Y2/(D1+D2) of the distance Y2 from the downstream end of the first protruding portion to the apex of the recess in the first direction to the distance D1+D2 from the downstream end of the first protruding portion to the downstream end of the second protruding portion is within a range of 1.26≥Y2/(D1+D2)≥ 0.74.

In the cooler according to the above embodiment, a plurality of sets of a wiring board and a semiconductor element can be mounted on a back surface of the first surface of the top plate along the first direction, and the corrugated bottom surface has the same corrugation in each of regions overlapping the wiring board in a plan view.

The semiconductor device according to the above-described embodiment includes the cooler, and a wiring board and a semiconductor element mounted on a back surface of the first surface of the top plate in the cooler.

As described above, the present invention has an effect that cooling performance of a cooler applied to a semiconductor device can be improved, and in particular, it is useful to apply the present invention to a semiconductor device having a high calorific value during operation, such as a semiconductor device for industrial use or an electric device.

What is claimed is:

1. A cooler comprising:
a top plate having a first surface that is flat;
a bottom plate having a second surface that is opposite to the first surface of the top plate and is corrugated, the first surface and the second surface facing a flow path of a refrigerant; and
a plurality of protruding portions protruding from the second surface of the bottom plate toward the first surface of the top plate, wherein
the refrigerant flows into the cooler in a first direction, and flows through the flow path;
any two of the plurality of protruding portions that are immediately upstream or downstream to each other are spaced apart by a first distance in the first direction, and by a second distance in a second direction orthogonal to the first direction, and
the corrugated second surface of the bottom plate has peaks and valleys that alternately appear in the first direction, and that form a waveform extending in the second direction.

2. The cooler according to claim 1, wherein
said any two of the plurality of protruding portions includes a first protruding portion, and a second protruding portion that is immediately upstream to the first protruding portion, and
in the first direction,
one of the peaks is positioned between a center of the first protruding portion and a downstream end of the second protruding portion, and
one of the valleys is positioned between an upstream end of the first protruding portion and a center of the second protruding portion.

3. The cooler according to claim 1, wherein a distance in the first direction between each of the valleys and one of the peaks immediately downstream thereto is shorter than a distance in the first direction between said each valley and one of the peaks immediately upstream thereto.

4. The cooler according to claim 1, wherein
the top plate has another surface opposite to the first surface, the another surface having a region for a semiconductor element to be mountable therein, and
in a plan view of the cooler, between two of the peaks, a distance in height between the first surface of the top plate and one of the two peaks that is closer to a center of said region is shorter than a distance in height between the first surface and the other of the two peaks.

5. The cooler according to claim 1, wherein a distance in height between one of the peaks positioned most downstream in the first direction and the first surface of the top plate is longest among all of the peaks.

6. The cooler according to claim 1, wherein
a ratio H1/H2 satisfies 1.4≥H1/H2≥0.2, wherein
H1 is a distance in height between one of the peaks and one of the valleys immediately adjacent thereto in the first direction, and
H2 is a distance in height between said one peak and one of the protruding portions immediately adjacent thereto in the second direction.

7. The cooler according to claim 2, wherein
a ratio Y1/(D1+D2) satisfies 1.0> Y1/(D1+D2)≥0.5, wherein
Y1 is a distance in the first direction between a downstream end of the first protruding portion and one of the peaks immediately adjacent thereto in the first direction, and
D1+D2 is a distance in the first direction between the downstream end of the first protruding portion and the downstream end of the second protruding portion.

8. The cooler according to claim 2, wherein
a ratio Y2/(D1+D2) satisfies 1.26≥ Y2/(D1+D2)≥0.74, wherein
Y2 is a distance in the first direction between a downstream end of the first protruding portion to one of the valleys immediately adjacent thereto in the first direction, and
D1+D2 is a distance in the first direction between the downstream end of the first protruding portion and the downstream end of the second protruding portion.

9. The cooler according to claim 1, wherein
the top plate has another surface opposite to the first surface, the another surface having a plurality of regions for a plurality of wiring boards to be mounted therein, and
the second surface of the bottom plate has a same corrugation in the plurality of regions overlapping the wiring boards in a plan view.

10. A semiconductor device comprising:
the cooler according to claim 1; and
a wiring board and a semiconductor element mounted on another surface of the top plate opposite to the first surface.
